(19) United States
(12) Patent Application Publication
(10) Pub. No.: US 2026/0153585 A1
(43) Pub. Date: Jun. 4, 2026

(54) Non-Contact Voltage Tester

(71) Applicant: Robert Bosch GmbH, Stuttgart (DE)

(72) Inventors: Chi Fung Chan, Ostfildern (DE); Ann-Kathrin Hahmann, Stuttgart (DE); Jianbang Ying, Hangzhou (CN); Kunal Shyamadas Burman, Echterdingen (DE); Thomas Kohlert, Nerja (ES); Xinhui Zhang, Hangzhou (CN)

(21) Appl. No.: 19/405,787

(22) Filed: Dec. 2, 2025

(30) Foreign Application Priority Data
Dec. 3, 2024 (DE) 10 2024 211 530.4

(51) Int. Cl. G01R 35/02; G01R 1/07; G01R 1/20; G01R 1/38; G01R 19/25; G01R 19/32; G01R 33/07

(52) U.S. Cl. CPC G01R 35/02; G01R 1/07; G01R 1/206; G01R 19/2503; G01R 1/38; G01R 19/32; G01R 33/072

(57) ABSTRACT

A non-contact voltage tester includes a microcontroller communicatively connected to the following components: (i) a probe for detecting a voltage based on electromagnetic or electrical field induction, (ii) at least two output devices, which provide an optical, acoustic and/or mechanical output based on a voltage detected by the probe, (ii) a switch, wherein the switch connects to an analog-digital conversion channel of the microcontroller to the respective output device. A method, a computer program, a device, and a storage medium for this purpose are also disclosed.

This application claims priority under 35 U.S.C. § 119 to patent application no. DE 10 2024 211 530.4, filed on Dec. 3, 2024 in Germany, the disclosure of which is incorporated herein by reference in its entirety.

The disclosure relates to a non-contact voltage tester. The disclosure further relates to a method, a computer program, a device, and a storage medium for this purpose.

### BACKGROUND

Non-contact voltage testers (NCVT) are designed to detect electrical voltage fields in leads and equipment without the need for direct contact with the live conductor. Non-contact voltage testers are widely used in electrical engineering to ensure the safety of professionals and users by providing a quick and easy way to detect the presence of hazardous voltages. In order to ensure a functionality of the non-contact voltage tester, the latter performs a self-test of its components.

The current prior art solution for this self-test has severe limitations on both the component and the circuit level due to limited analog-digital converter (ADC) channels in microcontrollers of the non-contact voltage tester. This limitation of the analog-digital converter (ADC) channels also restricts an extension of product functions as part of the self-test of the non-contact voltage tester.

### SUMMARY

The subject matter of the disclosure is a non-contact voltage tester, a method, a computer program, a device and a computer-readable storage medium having the features set forth below. Further features and details of the disclosure will emerge from the description and the drawings. Features and details which are described in connection with the non-contact voltage tester according to the disclosure naturally also apply in connection with the method according to the disclosure, the computer program according to the disclosure, the device according to the disclosure as well as the computer-readable storage medium according to disclosure, and vice versa in each case, so that a reciprocal reference is always possible with regard to the disclosure of the disclosure.

The object of the disclosure is in particular a non-contact voltage tester comprising a microcontroller communicatively connected to the following components:
a probe for detecting a voltage based on electromagnetic or electrical field induction,
at least two output devices, which provide an optical, acoustic and/or mechanical output based on a voltage detected by the probe,
a switch, wherein the switch connects an analog-digital conversion channel of the microcontroller to the respective output devices.

In other words, a non-contact voltage tester controlled by a microcontroller comprising a probe, two or more output devices, and a switch is described. In particular, the probe measures electrical voltages using electromagnetic or electrical field induction. The microcontroller may process these measured values and provide an optical, audible, and/or mechanical indication of the detected voltage when a voltage is detected by the probe via the output devices. The switch allows in particular at least two output devices to be connected via a single analog-digital conversion channel of the microcontroller, whereby advantageously a required number of analog-digital conversion channels can be reduced. It can be provided that at least the buzzer and the vibratory motor are connected to the analog-digital conversion channel of the microcontroller via the switch.

In a further option, it may be provided that the at least two output devices are selected from:
a buzzer to provide the acoustic output,
a vibratory motor to provide the mechanical output, in particular haptic feedback about a vibration,
a voltage light diode to provide the optical output.
   The respective acoustic, mechanical and/or optical output occurs in particular when a voltage is detected via the probe. The voltage light diode is thus provided to illuminate, for example, when a voltage is detected via the probe. As a result, a diverse and configurable output of information can be provided to the user. The combination of acoustic, mechanical and optical signals allows a clear and differentiated warning about the detected voltage. For example, this helps improve usability and safety as a user may perceive different types of signals regardless of individual sensory preferences or environmental conditions.

It may be advantageous if, in the context of the disclosure, the switch is an analog DPST switch. A DPST (Double Pole, Single Throw) analog switch is in particular an electrical switch that can switch two separate circuits on or off simultaneously. “Double pole” means that the switch controls two contacts (poles) while “Single Throw” indicates that the switch has only one on-off position. In particular, there are therefore no intermediate positions; both circuits are connected or disconnected simultaneously. Advantageously, two separate circuits can be controlled in parallel with a DPST switch. Since both circuits can be completely disconnected, this in particular increases electrical safety, for example in systems that rely on separate voltage sources.

For example, it may be contemplated that the non-contact voltage tester further comprises at least one mode of operation light diode, wherein the at least one mode of operation light diode is indicative of a sensitivity setting of the non-contact voltage tester. This has in particular the advantage that a user can visually overview the sensitivity setting of the non-contact voltage tester. The ability to display the mode of operation by the at least one light emitting mode of operation diode allows the user to easily and intuitively read the current sensitivity setting at any time. In particular, the sensitivity represents a threshold value for electromagnetic or electrical field induction from which the probe of the non-contact voltage tester detects a voltage.

In a further option, it may be provided that the non-contact voltage tester further comprises at least one of the following further components, wherein the switch connects the analog-digital conversion channel of the microcontroller to the at least one further component:
At least one interface, in particular a wireless interface, configured to transmit an output to an external data processing device based on the voltage detected by the probe,
At least one Hall sensor for further detecting a magnetic field with the non-contact voltage tester,
at least one Lidar sensor to determine a distance of the non-contact voltage tester to an obstruction,
at least one temperature sensor.
   For example, the interface may be a Wi-Fi or Bluetooth interface. For example, the external data processing device may be a computer or smartphone of a user. The Hall sensor allows the detection of magnetic fields, whereby an area of application of the voltage detector can be extended. The Lidar sensor allows for the measurement of distance to obstacles, which can increase the safety and precision of the device when used in complex environments. The integration of the temperature sensor may allow monitoring of an operating temperature of the voltage detector and may extend its service life. These additional functions particularly contribute to increasing the performance and breadth of application of the non-contact voltage tester.

The subject matter of the disclosure is also a method for performing a self-test of a non-contact voltage tester according to description herein comprising:
checking the at least two output devices and/or the at least one further component of the non-contact voltage tester using the switch, for example, by electrically controlling the at least two output devices and/or the at least one further component to determine an existing short circuit or line break,
initiating an output based on a result of the checking, for example visually via a display unit of the non-contact voltage tester or acoustically via a speaker of the non-contact voltage tester.
   The method according to the disclosure thus has the same advantages as those described in detail with reference to the non-contact voltage tester according to the disclosure. Checking the at least two output devices and/or the at least one further component of the non-contact voltage tester may be performed in a particular order. Further, as part of the self-test, a battery or rechargeable battery level of the non-contact voltage tester can be checked.

Another object of the disclosure is a computer program, in particular a computer program product, comprising commands which, when the computer program is executed by the non-contact voltage tester, cause the computer to carry out the method according to the disclosure by the microcontroller of the non-contact voltage tester. The computer program according to the disclosure thus brings with it the same advantages as have been described in detail with reference to a method according to the disclosure.

The disclosure also relates to a device for data processing which is configured so as to carry out the method according to the disclosure. For example, at least one computer or microcomputer or microcontroller that executes the computer program according to the disclosure and is preferably integrated in or communicatively connected to the non-contact voltage tester may be provided as the device. The device for data processing can comprise at least one processor for executing the computer program. A non-volatile data memory can be provided as well, in which the computer program can be stored and from which the computer program can be read by the processor for execution.

The disclosure can also relate to a computer-readable storage medium, which comprises the computer program according to the disclosure and/or commands that, when executed by the non-contact voltage tester according to the disclosure, prompt said computer program to carry out the method according to the disclosure. The storage medium is configured as a data memory such as a hard drive and/or a non-volatile memory and/or a memory card, for example. The storage medium can, for example, be integrated into the computer.

In addition, the method according to the disclosure can also be designed as a computer-implemented method. Alternatively or additionally, at least one of the disclosed method steps may be computer-implemented and/or performed automatically.

### BRIEF DESCRIPTION OF THE DRAWINGS

Further advantages, features, and details of the disclosure emerge from the following description, in which exemplary embodiments of the disclosure are described in detail with reference to the drawings. The features mentioned in the claims and in the description can each be essential to the disclosure individually or in any combination. It shows:

FIG. 1 a schematic visualization of a method, a device, a storage medium, and a computer program according to exemplary embodiments of the disclosure,

FIG. 2 a schematic illustration of a non-contact voltage tester according to exemplary embodiments of the disclosure.

### DETAILED DESCRIPTION

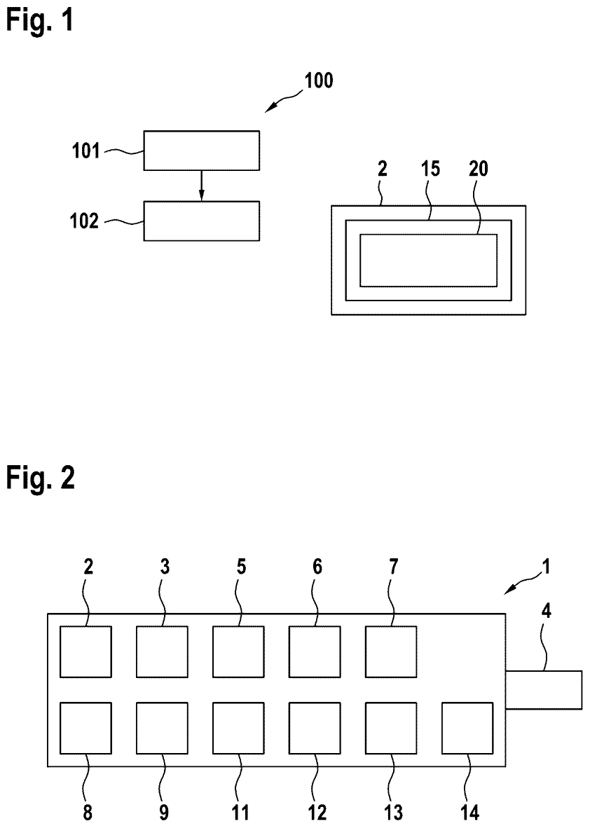

FIG. 1 schematically illustrates a method 100, a device 10, a storage medium 15, and a computer program 20 according to exemplary embodiments of the disclosure.

In particular, FIG. 1 shows a method 100 for performing a self-test of a non-contact voltage tester 1 according to the disclosure. In a first step 101, the at least two output devices and/or the at least one further component of the non-contact voltage tester 1 are checked using the switch 8. In a second step 102, an output is initiated based on a result of the checking.

FIG. 2 shows a schematic representation of a non-contact voltage tester 1 according to exemplary embodiments of the disclosure. This comprises a microcontroller 2, a buzzer 3, a probe 4, a vibratory motor 5, a voltage light diode 6, a mode light diode 7, a switch 8, an analog-digital converter 9, an interface 11, in particular, wireless interface, which is configured to transmit the optical, transmit acoustic and/or mechanical output to an external data processing device, a Hall sensor 12, to further detect a magnetic field with the non-contact voltage tester 1, a Lidar sensor 13, to determine a distance of the non-contact voltage tester 1 to an obstruction, and a temperature sensor 14.

The buzzer 3 is in particular configured to provide an acoustic output. The vibratory motor 5 is particularly configured to provide mechanical output. The voltage light diode 6 is in particular configured to provide an optical output. In particular, the mode of operation light diode 7 indicates a sensitivity setting of the non-contact voltage tester 1. The switch 8 is preferably an analog DPST switch.

At least the buzzer 3 and the vibratory motor 5 are preferably connected to the analog-digital conversion channel 9 of the microcontroller 2 via the switch 8.

A self-test of a non-contact voltage tester 1 is used in particular to ensure that all HMI (Human Machine Interface) components and sensor circuits operate in a systematic order.

A single sensing/ballast resistor may be used in the non-contact voltage tester 1 as part of the self-test according to exemplary embodiments. An additional switch 8 in the sensor circuit may be used to facilitate data collection. Moreover, a plurality of switches 8 may be used to further reduce the number of analog-digital converters 9. As a result, several components of the non-contact voltage tester 1 can advantageously be tested in the self-test with a single analog-digital converter 9.

The above explanation of the embodiments describes the present disclosure solely within the scope of examples. Of course, individual features of the embodiments can be freely combined with one another, if technically feasible, without leaving the scope of the present disclosure.

What is claimed is:

1. A non-contact voltage tester, comprising:
a microcontroller;
a probe configured to detect a voltage based on electromagnetic or electrical field induction;
at least two output devices, which are configured to provide an optical, acoustic and/or mechanical output based on a voltage detected by the probe;
a switch configured to connect an analog-digital conversion channel of the microcontroller to the respective output device,
wherein the microcontroller is communicatively connected to the probe, the at least two output devices, and the switch.

2. The non-contact voltage tester according to claim 1, wherein the at least two output devices are selected from:
a buzzer configured to provide the acoustic output,
a vibratory motor configured to provide the mechanical output, and
a voltage light diode configured to provide the optical output.

3. The non-contact voltage tester according to claim 2, wherein at least the buzzer and the vibratory motor are connected to the analog/digital conversion channel of the microcontroller via the switch.

4. The non-contact voltage tester according to claim 1, wherein the switch is an analog DPST switch.

5. The non-contact voltage tester according to claim 1, further comprising at least one mode of operation light diode, wherein the at least one mode of operation light diode is indicative of a sensitivity setting of the non-contact voltage tester.

6. The non-contact voltage tester according to claim 1, further comprising at least one of the following additional components: (i) at least one interface configured to transmit an output to an external data processing device based on the voltage detected by the probe, (ii) at least one Hall sensor configured to further detect a magnetic field with the non-contact voltage tester, (iii) at least one Lidar sensor configured to determine a distance of the non-contact voltage tester to an obstruction, and (iv) at least one temperature sensor,
wherein the switch is configured to connect the analog/digital conversion channel of the microcontroller to the at least one additional component(s).

7. A method for performing a self-test of the non-contact voltage tester according to claim 1, the method comprising:
checking the at least two output devices and/or the at least one additional component(s) of the non-contact voltage tester using the switch; and
initiating an output based on a result of the checking.

8. A computer program, comprising instructions which, when the computer program is executed by the non-contact voltage tester according to claim 1, causes the non-contact voltage tester to execute the following method:
checking the at least two output devices and/or the at least one of the additional components of the non-contact voltage tester using the switch; and
initiating an output based on a result of the checking.

9. A device for data processing, configured so as to carry out the method according to claim 7.

10. A computer-readable storage medium, comprising commands which, when executed by the non-contact voltage tester according to claim 1, causes the non-contact voltage tester to carry out the following steps:
checking the at least two output devices and/or the at least one of the additional components of the non-contact voltage tester using the switch; and
initiating an output based on a result of the checking.

11. The non-contact voltage tester according to claim 6, wherein the at least one interface is a wireless interface.
